(19) United States
(12) Patent Application Publication
(10) Pub. No.: US 2026/0243823 A1
(43) Pub. Date: Aug. 20, 2026

(54) SEMICONDUCTOR INTEGRATED CIRCUIT

(71) Applicant: CANON KABUSHIKI KAISHA, Tokyo (JP)

(72) Inventor: ARATA YAMAMOTO, Kanagawa (JP)

(21) Appl. No.: 19/537,709

(22) Filed: Feb. 12, 2026

(30) Foreign Application Priority Data
Feb. 17, 2025 (JP) 2025-023552

(51) Int. Cl. G01R 31/3185

(52) U.S. Cl. CPC G01R 31/318572; G01R 31/318541

(57) ABSTRACT

A semiconductor integrated circuit includes a test circuit that tests an operation of the semiconductor integrated circuit, a TEG circuit that shares at least a part of circuitry with the test circuit and is used for characteristic evaluation of the semiconductor integrated circuit or a manufacturing process, and a switching circuit that switches between a first operation mode for operating the test circuit in response to a first input signal and a second operation mode for operating the TEG circuit in response to a second input signal.

### BACKGROUND

### Field of the Technology

The present disclosure relates to a semiconductor integrated circuit.

### Description of the Related Art

In order to evaluate characteristics of a semiconductor integrated circuit or a manufacturing process, a test element group (TEG) may be provided on a semiconductor wafer. When the TEG is provided in a chip region of the semiconductor wafer, an increase in circuit area due to the TEG may be suppressed. For example, in an electrical characteristic evaluation circuit of a semiconductor device disclosed in Japanese Patent Laid-Open No. 2000-058614, an increase in circuit area due to the TEG is suppressed by stacking a plurality of TEGs.

However, in Japanese Patent Laid-Open No. 2000-058614, when a test circuit for testing an operation of the semiconductor device is further provided in addition to the TEG circuit, the circuit area may increase.

### SUMMARY

Therefore, the present disclosure is directed to provide a semiconductor integrated circuit capable of suppressing an increase in a circuit area.

According to one aspect of the present specification, there is provided a semiconductor integrated circuit that includes a test circuit configured to test an operation of the semiconductor integrated circuit, a test element group (TEG) circuit configured to share at least a part of circuitry with the test circuit and be used for characteristic evaluation of the semiconductor integrated circuit or a manufacturing process, and a switching circuit configured to switch between a first operation mode for operating the test circuit in response to a first input signal and a second operation mode for operating the TEG circuit in response to a second input signal.

Features of the present disclosure will become apparent from the following description of embodiments with reference to the attached drawings. The following description of embodiments is described by way of example.

### BRIEF DESCRIPTION OF THE DRAWINGS

FIG. 1 is a circuit diagram of a semiconductor integrated circuit according to a first embodiment.

FIGS. 2A, 2B, 2C and 2D are diagrams illustrating an example of a TEG according to the first embodiment.

FIG. 3 is a circuit diagram of a semiconductor integrated circuit according to a second embodiment.

FIGS. 4A and 4B are diagrams illustrating an example of a TEG according to the second embodiment.

FIG. 5 is a circuit diagram of a semiconductor integrated circuit according to a third embodiment.

FIGS. 6A, 6B and 6C are diagrams illustrating an example of a TEG according to the third embodiment.

FIG. 7 is a block diagram of an equipment according to a fourth embodiment.

FIGS. 8A and 8B are block diagrams of an equipment according to a fifth embodiment.

### DESCRIPTION OF THE EMBODIMENTS

### First Embodiment

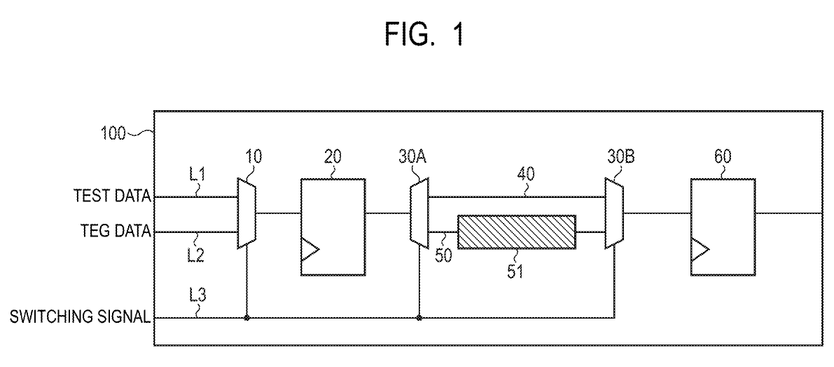

FIG. 1 is a circuit diagram of a semiconductor integrated circuit 100 according to the present embodiment. In a semiconductor wafer having a plurality of chip regions and dicing regions for separating each of the plurality of chip regions, the semiconductor integrated circuit 100 is formed in the chip region (semiconductor chip).

When the semiconductor integrated circuit 100 is formed, characteristics of the semiconductor integrated circuit 100 or a manufacturing process are evaluated, and an operation of the semiconductor integrated circuit 100 is tested. The semiconductor integrated circuit 100 includes a test circuit for testing the operation of the semiconductor integrated circuit 100, and a TEG circuit for evaluating characteristics of the semiconductor integrated circuit 100 or a manufacturing process. The semiconductor integrated circuit 100 further includes a circuit under test (not illustrated) to be tested for the operation of the semiconductor integrated circuit 100.

The test circuit includes a signal line L1, a control line L3, a multiplexer 10, a first flip-flop 20, a first multiplexer 30A, a second multiplexer 30B, a first transmission path 40, and a second flip-flop 60.

The TEG circuit includes a signal line L2, the control line L3, the multiplexer 10, the first flip-flop 20, the first multiplexer 30A, the second multiplexer 30B, a second transmission path 50, and the second flip-flop 60.

The multiplexer 10, the first multiplexer 30A, and the second multiplexer 30B are examples of a switching circuit. The first flip-flop 20 is an example of a first storage element, and the second flip-flop 60 is an example of a second storage element.

The signal line L1 is formed of a conductive member and is connected to a first external terminal (not illustrated) by wire bonding. The signal line L1 is connected to an external device installed outside the semiconductor integrated circuit 100 via the first external terminal and transmits test data (first input signal) from the external device. The test data is data for testing an operation of the circuit under test.

The signal line L2 is formed of a conductive member and is connected to a second external terminal (not illustrated) by wire bonding. The signal line L2 is connected to an external device via the second external terminal and transmits TEG data (second input signal) from the external device. The TEG data is data for evaluating characteristics of the semiconductor integrated circuit 100 or a manufacturing process.

The control line L3 is formed of a conductive member and is connected to a third external terminal (not illustrated) by wire bonding. The control line L3 is connected to an external device via the third external terminal and transmits a switching signal from the external device. The switching signal is a signal for switching between a test mode (first operation mode) and a TEG mode (second operation mode). The test mode is a mode in which the test circuit is operated in accordance with test data. The TEG mode is a mode in which the TEG circuit is operated in accordance with TEG data.

The multiplexer 10 receives the test data from the signal line L1, receives the TEG data from the signal line L2, and receives the switching signal from the control line L3. The multiplexer 10 outputs the test data from the signal line L1 or the TEG data from the signal line L2 to the first flip-flop 20 in response to the switching signal.

The first flip-flop 20 holds the test data or the TEG data from the multiplexer 10. The first flip-flop 20 outputs the held test data or TEG data to the first multiplexer 30A.

A first transmission path 40 and a second transmission path 50 are provided in parallel between the first multiplexer 30A and the second multiplexer 30B. A TEG 51 is disposed on the second transmission path 50. The TEG 51 is a pattern used for characteristic evaluation of the semiconductor integrated circuit 100 or a manufacturing process.

The first multiplexer 30A receives test data or TEG data from the first flip-flop 20. The first multiplexer 30A receives a switching signal from the control line L3. The first multiplexer 30A outputs the test data from the first flip-flop 20 to the first transmission path 40 or outputs the TEG data from the first flip-flop 20 to the second transmission path 50 in response to the switching signal.

The second multiplexer 30B receives the test data from the first transmission path 40 or the TEG data from the second transmission path 50. The second multiplexer 30B receives the switching signal from the control line L3. The second multiplexer 30B outputs the test data from the first transmission path 40 or the TEG data from the second transmission path 50 to the second flip-flop 60 in response to the switching signal.

The second flip-flop 60 holds the test data from the first transmission path 40 or the TEG data from the second transmission path 50. The second flip-flop 60 outputs the test data to the circuit under test and outputs the TEG data to the external device.

The operation of the semiconductor integrated circuit 100 in the test mode will be described. In the test mode, the multiplexer 10 outputs test data from the signal line L1 to the first flip-flop 20. The first flip-flop 20 holds the test data from the multiplexer 10. The first flip-flop 20 outputs the held test data to the first multiplexer 30A. The first multiplexer 30A outputs the test data from the first flip-flop 20 to the first transmission path 40, and the second multiplexer 30B outputs the test data from the first transmission path 40 to the second flip-flop 60. The second flip-flop 60 holds the test data from the second multiplexer 30B. For example, the first flip-flop 20 and the second flip-flop 60 output the test data to the circuit under test. The external device verifies the operation of the circuit under test based on an output signal from the circuit under test.

The operation of the semiconductor integrated circuit 100 in the TEG mode will be described. In the TEG mode, the multiplexer 10 outputs TEG data from the signal line L2 to the first flip-flop 20. The first flip-flop 20 holds the TEG data from the multiplexer 10. The first flip-flop 20 outputs the held TEG data to the first multiplexer 30A. The first multiplexer 30A outputs the TEG data from the first flip-flop 20 to the second transmission path 50, and the second multiplexer 30B outputs the TEG data from the second transmission path 50 to the second flip-flop 60. The second flip-flop 60 holds the TEG data from the second transmission path 50. The second flip-flop 60 outputs the held TEG data to the external device. The external device evaluates the characteristics of the semiconductor integrated circuit 100 or the manufacturing process based on the TEG data from the second flip-flop 60.

As described above, according to the semiconductor integrated circuit 100, the TEG circuit shares at least a part of circuitry with the test circuit. Specifically, the TEG circuit shares the first flip-flop 20 and the second flip-flop 60 with the test circuit. Thus, the semiconductor integrated circuit 100 can suppress an increase in the circuit area as compared with a case where a dedicated flip-flop is used to configure a TEG circuit as in the related art.

In addition, the semiconductor integrated circuit 100 can share a power supply and a power supply pad in the test circuit and the TEG circuit. As a result, the semiconductor integrated circuit 100 can suppress an increase in the circuit area as compared with the case where the test circuit and the TEG circuit are independently provided, respective power supplies and power supply pads are provided as in the related art. In addition, the semiconductor integrated circuit 100 can reduce a degree of difficulty in forming the TEG circuit as compared with a case where a plurality of TEGs are stacked to suppress an increase in circuit area as in the related art.

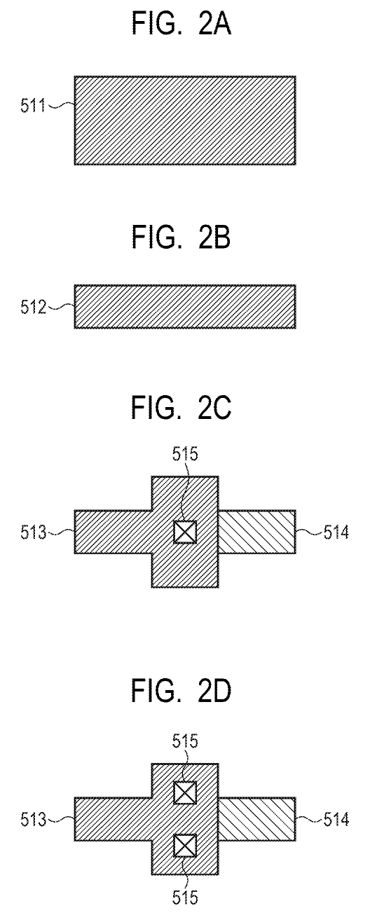

FIGS. 2A to 2D are diagrams illustrating an example of the TEG 51 according to the present embodiment. FIG. 2A illustrates an interconnect 511, and FIG. 2B illustrates an interconnect 512 that is thinner than the interconnect 511. FIG. 2C illustrates a pattern for electrically connecting an interconnect 513 and an interconnect 514 through one via 515, and FIG. 2D illustrates a pattern for electrically connecting the interconnect 513 and the interconnect 514 through two vias 515. The characteristics of the manufacturing process are evaluated by using the patterns of FIGS. 2A to 2D as the TEG 51.

One or more TEGs 51 may be arranged in the TEG circuit. When a plurality of TEGs 51 are arranged, a plurality of transmission paths for the TEGs are provided between the first multiplexer 30A and the second multiplexer 30B. For example, when a third transmission path is provided in parallel with the second transmission path 50, the interconnect 511 may be disposed on the second transmission path 50, and the interconnect 512 may be disposed on the third transmission path. As described above, the plurality of TEGs 51 may be the interconnects 511 and 512 having different widths. As illustrated in FIGS. 2C and 2D, the plurality of TEGs 51 may have different numbers of vias 515 or different shapes of vias (not illustrated).

Since the TEG 51 is disposed not in the dicing region of the semiconductor wafer but in the chip region, the semiconductor integrated circuit 100 can suppress the occurrence of film peeling at the time of dicing. In addition, compared to the case where the TEG 51 is disposed in the dicing region, the semiconductor integrated circuit 100 can increase the degree of freedom in disposing the TEG 51.

### Second Embodiment

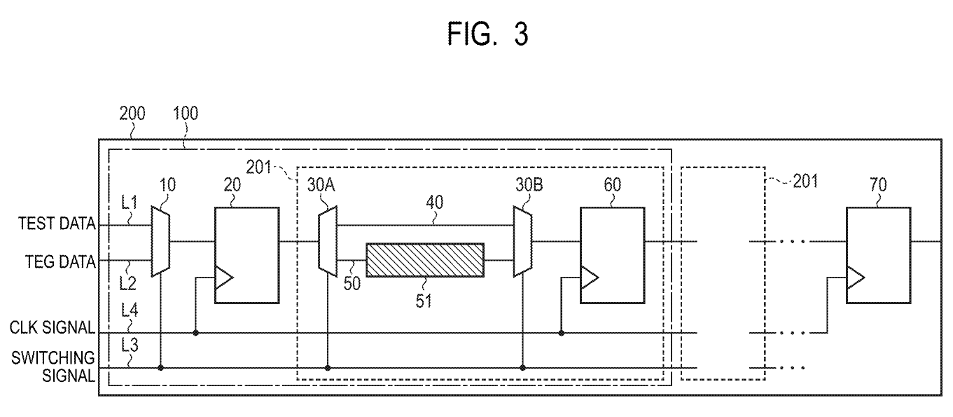

FIG. 3 is a circuit diagram of a semiconductor integrated circuit 200 according to the present embodiment. The semiconductor integrated circuit 200 differs from the semiconductor integrated circuit 100 according to the first embodiment in that it includes a plurality of circuit blocks 201. In the present embodiment, the same components as those of the semiconductor integrated circuit 100 according to the first embodiment are denoted by the same reference numerals, and detailed description thereof is omitted.

The semiconductor integrated circuit 200 includes signal lines L1 and L2, a control line L3, a CLK signal line L4, a multiplexer 10, a first flip-flop 20, a plurality of circuit blocks 201, and a third flip-flop (third storage element) 70.

Each of the plurality of circuit blocks 201 includes a test circuit and a TEG circuit. The test circuit includes a control line L3, a CLK signal line L4, a first multiplexer 30A, a second multiplexer 30B, a first transmission path 40, and a second flip-flop 60. The TEG circuit includes the control line L3, the CLK signal line L4, the first multiplexer 30A, the second multiplexer 30B, a second transmission path 50, and the second flip-flop 60.

The plurality of circuit blocks 201 includes first to N-th circuit blocks 201. N is an integer of 2 or more. The first to N-th circuit blocks 201 are connected in series. Specifically, the second circuit block 201 is connected to the first circuit block 201, the third circuit block 201 is connected to the second circuit block 201, and the N-th circuit block 201 is connected to the (N-1)-th circuit block 201.

More specifically, the first multiplexer 30A of the second circuit block 201 is connected to the second flip-flop 60 of the first circuit block 201. The first multiplexer 30A of the third circuit block 201 is connected to the second flip-flop 60 of the second circuit block 201. The first multiplexer 30A of the N-th circuit block 201 is connected to the second flip-flop 60 of the (N-1)-th circuit block 201. The second flip-flop 60 of the N-th circuit block 201 is connected to the third flip-flop 70. The third flip-flop 70 holds test data or TEG data output from a final-stage circuit block (N-th circuit block) 201 among the plurality of circuit blocks 201. The third flip-flop 70 is connected to an external device, and outputs the test data or the TEG data from the N-th circuit block 201 to the external device. The first multiplexer 30A of the first circuit block 201 is connected to the first flip-flop 20. The first flip-flop 20, the second flip-flop 60 of the first to N-th circuit blocks 201, and the third flip-flop 70 are connected to the CLK signal line L4 and hold test data or TEG data according to a CLK signal from the CLK signal line L4.

The operation of the semiconductor integrated circuit 200 in the test mode will be described. In the test mode, a plurality of flip-flops of the semiconductor integrated circuit 200 are connected in series to form a shift register (scan chain). Specifically, the first flip-flop 20, the second flip-flop 60 of the first to N-th circuit blocks 201, and the third flip-flop 70 are connected in series to form a shift register. The shift register is one of the methods used in DFT (Design For Testability). By forming the shift register, test data can be efficiently set in the circuit under test.

In the test mode, the multiplexer 10 outputs test data from the signal line L1 to the first flip-flop 20. The first flip-flop 20 holds the test data from the multiplexer 10 in response to the CLK signal from the CLK signal line L4. The first flip-flop 20 outputs the held test data to the first circuit block 201.

In the first circuit block 201, the first multiplexer 30A outputs the test data from the first flip-flop 20 to the first transmission path 40, and the second multiplexer 30B outputs the test data from the first transmission path 40 to the second flip-flop 60. The second flip-flop 60 holds the test data from the second multiplexer 30B in accordance with the CLK signal, and outputs the held test data to the second circuit block 201.

In the second circuit block 201, the first multiplexer 30A outputs the test data from the second flip-flop 60 of the first circuit block 201 to the first transmission path 40. The second multiplexer 30B outputs the test data from the first transmission path 40 to the second flip-flop 60. In the second circuit block 201, the second flip-flop 60 holds the test data from the first transmission path 40 in accordance with the CLK signal, and outputs the held test data to the third circuit block 201. The third to N-th circuit blocks 201 operate in the same manner as the first and second circuit blocks 201.

As described above, the first flip-flop 20, the second flip-flop 60 of the first to N-th circuit blocks 201, and the third flip-flop 70 sequentially shift the test data according to the CLK signal. Each flip-flop holds the test data. For example, each flip-flop outputs the test data to the circuit under test. The external device verifies the operation of the circuit under test based on an output signal from the circuit under test.

The operation of the semiconductor integrated circuit 200 in the TEG mode will be described. In the TEG mode, the first flip-flop 20, the second flip-flop 60 of the first to N-th circuit blocks 201, and the third flip-flop 70 form a shift register and sequentially shift TEG data. Specifically, the multiplexer 10 outputs TEG data from the signal line L2 to the first flip-flop 20. The first flip-flop 20 holds the TEG data from the multiplexer 10 in accordance with a CLK signal, and outputs the held TEG data to the first circuit block 201.

In the first circuit block 201, the first multiplexer 30A outputs the TEG data from the first flip-flop 20 to the first transmission path 40, and the second multiplexer 30B outputs the TEG data from the first transmission path 40 to the second flip-flop 60. The second flip-flop 60 holds the TEG data from the first transmission path 40 in accordance with the CLK signal, and outputs the held TEG data to the second circuit block 201.

In the second circuit block 201, the first multiplexer 30A outputs the TEG data from the second flip-flop 60 of the first circuit block 201 to the first transmission path 40. The second multiplexer 30B outputs the TEG data from the first transmission path 40 to the second flip-flop 60. In the second circuit block 201, the second flip-flop 60 holds the TEG data from the first transmission path 40 in accordance with the CLK signal, and outputs the held TEG data to the third circuit block 201. The third to (N-1)-th circuit blocks 201 operate in the same manner as the first and second circuit blocks 201.

As described above, the first flip-flop 20 and the second flip-flop 60 of the first to (N-1)-th circuit blocks 201 sequentially shift the TEG data in accordance with the CLK signal, and each of the flip-flops holds the TEG data.

Next, in the first to N-th circuit blocks 201, the TEG data is transmitted to the second transmission path 50 in order to evaluate the characteristics of the TEG 51. Specifically, in the first circuit block 201, the first multiplexer 30A outputs the TEG data from the first flip-flop 20 to the second transmission path 50, and the second multiplexer 30B outputs the TEG data from the second transmission path 50 to the second flip-flop 60. In the second circuit block 201, the first multiplexer 30A outputs the TEG data from the second flip-flop 60 of the first circuit block 201 to the second transmission path 50. The second multiplexer 30B outputs the TEG data from the second transmission path 50 to the second flip-flop 60. The third to N-th circuit blocks 201 operate similarly.

Next, in the first to N-th circuit blocks 201, the TEG data from the second multiplexer 30B is held in the second flip-flop 60. Specifically, in the first circuit block 201, the second flip-flop 60 holds the TEG data from the second multiplexer 30B in accordance with the CLK signal. In the second circuit block 201, the second flip-flop 60 holds the TEG data from the second multiplexer 30B in accordance with the CLK signal. The third to N-th circuit blocks 201 operate similarly.

Next, in the first to N-th circuit blocks 201, the TEG data held in the second flip-flop 60 is sequentially output. Specifically, the second flip-flop 60 of the first to N-th circuit blocks 201 and the third flip-flop 70 form a shift register. The shift register sequentially transmits the TEG data of the second flip-flop 60 according to the CLK signal, and outputs the TEG data from the third flip-flop 70 to the external device. The external device evaluates the characteristics of the semiconductor integrated circuit 200 or the manufacturing process based on the TEG data of each of the first to N-th circuit blocks 201. According to the semiconductor integrated circuit 200, the characteristics can be evaluated based on the plurality of TEGs 51.

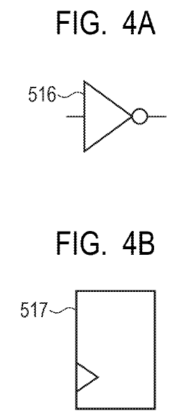

FIGS. 4A and 4B are diagrams illustrating an example of the TEG 51 according to the present embodiment. FIG. 4A illustrates an inverter 516 and FIG. 4B illustrates a flip-flop 517. The inverter 516 and the flip-flop 517 have logic functions and are TEGs for evaluating digital characteristics of the semiconductor integrated circuit 200. A transition fault can be evaluated as a digital characteristic of the semiconductor integrated circuit 200. For example, by detecting that the TEG data of the flip-flop 517 transitions from "0" to "1" or from "1" to "0" according to the CLK signal, the external device can evaluate the transition fault. Note that the TEG 51 is not limited thereto, and, for example, the TEGs of FIGS. 2A to 2D may be used.

### Third Embodiment

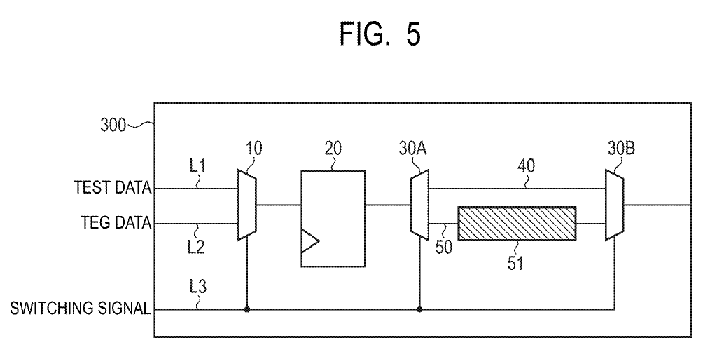

FIG. 5 is a circuit diagram of a semiconductor integrated circuit 300 according to the present embodiment. The semiconductor integrated circuit 300 differs from the semiconductor integrated circuit 100 according to the first embodiment in that it does not include the second flip-flop 60 of FIG. 1. In the present embodiment, the same components as those of the semiconductor integrated circuit 100 according to the first embodiment are denoted by the same reference numerals, and detailed description thereof is omitted.

The semiconductor integrated circuit 300 includes a test circuit and a TEG circuit. The test circuit includes a signal line L1, a control line L3, a multiplexer 10, a first flip-flop 20, a first multiplexer 30A, a second multiplexer 30B, and a first transmission path 40. The TEG circuit includes a signal line L2, the control line L3, the multiplexer 10, the first flip-flop 20, the first multiplexer 30A, the second multiplexer 30B, and a second transmission path 50.

In the TEG mode, the semiconductor integrated circuit 300 outputs TEG data from the second transmission path 50 to the external device without using a flip-flop. As compared with the case where the semiconductor integrated circuit 100 according to the first embodiment outputs the TEG data from the second transmission path 50 to the external device via the second flip-flop 60, the semiconductor integrated circuit 300 is less likely to be affected by the analog characteristics of the flip-flop. Thus, the semiconductor integrated circuit 300 can accurately evaluate the analog characteristics of the TEG 51.

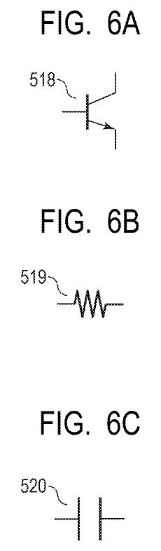

FIGS. 6A to 6C are diagrams illustrating an example of the TEG 51 according to the present embodiment. FIG. 6A illustrates a transistor 518, FIG. 6B illustrates a resistor 519, and FIG. 6C illustrates a capacitor 520. By using these TEGs, analog characteristics of a threshold voltage of the transistor 518, a value of the resistor 519, and a capacitance of the capacitor 520 can be evaluated.

### Fourth Embodiment

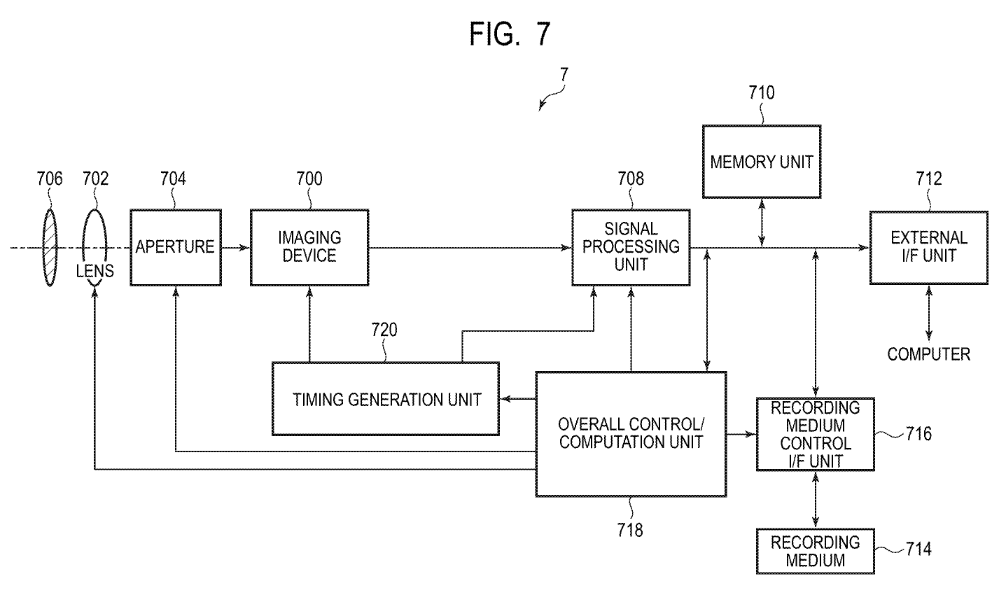

The semiconductor integrated circuit in the above-described embodiment is provided in a photoelectric conversion device, and the photoelectric conversion device can be applied to various equipment. Examples of the equipment include a digital still camera, a digital camcorder, a camera head, a copier, a fax machine, a mobile phone, an in-vehicle camera, an observation satellite, and a monitoring camera. FIG. 7 illustrates a block diagram of a digital still camera as an example of the equipment.

The equipment 7 illustrated in FIG. 7 includes a barrier 706, a lens 702, an aperture 704, and an imaging device 700 (an example of a photoelectric conversion device). The equipment 7 further includes a signal processing unit (processing device) 708, a timing generation unit 720, an overall control/computation unit 718 (control device), a memory unit 710 (storage device), a recording medium control I/F unit 716, a recording medium 714, and an external I/F unit 712. At least one of the barrier 706, the lens 702, and the aperture 704 is an optical device corresponding to the imaging device 700. The barrier 706 protects the lens 702, and the lens 702 forms an optical image of an object on the imaging device 700. The aperture 704 makes the amount of light passing through the lens 702 variable. The imaging device 700 is configured as in the above-described embodiment, and converts an optical image formed by the lens 702 into image data (image signal). The signal processing unit 708 performs various corrections, data compression, and the like on the image data output from the imaging device 700. The timing generation unit 720 outputs various timing signals to the imaging device 700 and the signal processing unit 708. The overall control/computation unit 718 controls the entire digital still camera, and the memory unit 710 temporarily stores image data. The recording medium control I/F unit 716 is an interface for recording or reading image data on or from the recording medium 714, and the recording medium 714 is a detachable recording medium such as a semiconductor memory for recording or reading image data. The external I/F unit 712 is an interface for communicating with an external computer or the like. The timing signal and the like may be input from the outside of the equipment 7. The equipment 7 may further include a display device (a monitor, an electronic viewfinder, or the like) that displays information obtained by the imaging device 700. The equipment 7 includes at least a photoelectric conversion device. Further, the equipment 7 includes at least one of an optical device, a control device, a processing device, a display device, a storage device, and a mechanical device that operates based on information obtained by the photoelectric conversion device. The mechanical device is a movable unit (for example, a robot arm) that operates by receiving a signal of the photoelectric conversion device.

Each pixel may include a plurality of photoelectric conversion units (a first photoelectric conversion unit and a second photoelectric conversion unit). The signal processing unit 708 may be configured to process the pixel signal based on the charge generated in the first photoelectric conversion unit and the pixel signal based on the charge generated in the second photoelectric conversion unit and acquire the distance information from the imaging device 700 to the object.

### Fifth Embodiment

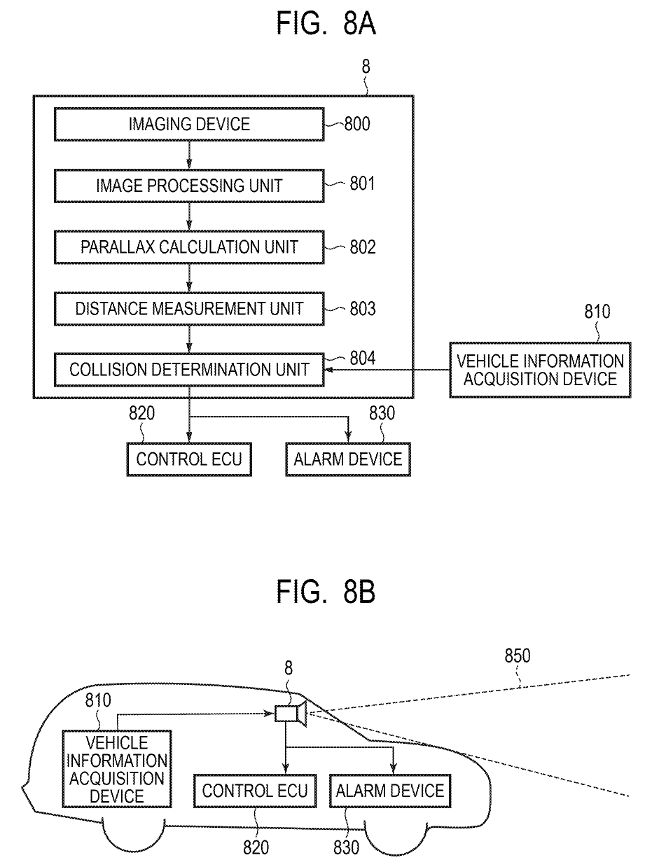

FIGS. 8A and 8B are block diagrams of an equipment 8 related to an in-vehicle camera according to the present embodiment. The equipment 8 includes an imaging device 800 (an example of a photoelectric conversion device having a semiconductor integrated circuit) and a signal processing device (processing device) that processes a signal from the imaging device 800. The equipment 8 includes an image processing unit 801 that performs image processing on a plurality of pieces of image data acquired by the imaging device 800, and a parallax calculation unit 802 that calculates parallax (phase difference of parallax images) from the plurality of pieces of image data acquired by the equipment 8. In addition, the equipment 8 includes a distance measurement unit 803 that calculates a distance to an object based on the calculated parallax, and a collision determination unit 804 that determines whether or not there is a possibility of collision based on the calculated distance. Here, the parallax calculation unit 802 and the distance measurement unit 803 are examples of a distance information acquisition unit that acquires distance information to the object. That is, the distance information is information related to a parallax, a defocus amount, a distance to the object, and the like. The collision determination unit 804 may determine the collision possibility using any of these pieces of distance information. The distance information acquisition unit may be realized by dedicatedly designed hardware or may be realized by a software module. Also, it may be realized by FPGA (Field Programmable Gate Array), ASIC (Application Specific Integrated Circuit) or a combination thereof.

The equipment 8 is connected to the vehicle information acquisition device 810 and can acquire vehicle information such as a vehicle speed, a yaw rate, and a steering angle. In addition, a control ECU 820, which is a control device that outputs a control signal for generating a braking force to the vehicle based on the determination result of the collision determination unit 804, is connected to the equipment 8. The equipment 8 is also connected to an alarm device 830 that issues an alarm to a driver based on the determination result of the collision determination unit 804. For example, when the determination result of the collision determination unit 804 indicates that the possibility of collision is high, the control ECU 820 performs vehicle control to avoid collision and reduce damage by, for example, applying a brake, returning an accelerator, or suppressing engine output. The alarm device 830 gives the alarm to the user by sounding an alarm, displaying alarm information on a screen of a car navigation system or the like, giving vibration to a seat belt or a steering wheel, or the like. The equipment 8 functions as a control unit that controls the operation of controlling the vehicle as described above.

In the present embodiment, the surroundings of the vehicle, for example, the front or the rear is imaged by the equipment 8. FIG. 8B illustrates an equipment in a case of capturing an image in front of the vehicle (imaging range 850). The vehicle information acquisition device 810 serving as the imaging control unit sends an instruction to the equipment 8 or the imaging device 800 to perform the imaging operation. With such a configuration, the accuracy of distance measurement can be further improved.

In the above description, an example in which control is performed so as not to collide with another vehicle has been described, but the present embodiment is also applicable to control in which automatic driving is performed so as to follow another vehicle, control in which automatic driving is performed so as not to protrude from a lane, and the like. Further, the equipment 8 is not limited to a vehicle such as an automobile, and can be applied to, for example, a ship, an aircraft, an artificial satellite, an industrial robot, a consumer robot, or the like mobile object (moving device). In addition, the present embodiment is not limited to a mobile object and can be widely applied to devices utilizing object recognition or biological recognition, such as an intelligent traffic system (ITS) and a monitoring system.

The present disclosure is not limited to the above embodiment, and various modifications are possible. For example, an example in which a partial configuration of one embodiment is added to another embodiment or an example in which a partial configuration of one embodiment is replaced with a partial configuration of another embodiment is also an embodiment of the present disclosure.

According to the present disclosure, it is possible to realize a semiconductor integrated circuit capable of suppressing an increase in circuit area.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-023552, filed Feb. 17, 2025, which is hereby incorporated by reference herein in its entirety.

What is claimed is:

1. A semiconductor integrated circuit comprising:
a test circuit configured to test an operation of the semiconductor integrated circuit;
a test element group (TEG) circuit configured to share at least a part of circuitry with the test circuit and be used for characteristic evaluation of the semiconductor integrated circuit or a manufacturing process; and
a switching circuit configured to switch between a first operation mode for operating the test circuit in response to a first input signal and a second operation mode for operating the TEG circuit in response to a second input signal.

2. The semiconductor integrated circuit according to claim 1,
wherein the test circuit includes a first storage element that constitutes the part of circuitry and holds the first input signal or the second input signal, and a first transmission path,
wherein the TEG circuit includes a second transmission path on which a TEG is disposed, and
wherein the switching circuit transmits the first input signal from the first storage element to the first transmission path in the first operation mode and transmits the second input signal from the first storage element to the second transmission path in the second operation mode.

3. The semiconductor integrated circuit according to claim 2, wherein the test circuit includes a second storage element that constitutes the part of circuitry and holds the first input signal from the first transmission path or the second input signal from the second transmission path.

4. The semiconductor integrated circuit according to claim 3,
wherein the switching circuit includes a first multiplexer and a second multiplexer,
wherein, in the first operation mode, the first multiplexer outputs the first input signal from the first storage element to the first transmission path, and the second multiplexer outputs the first input signal from the first transmission path to the second storage element, and
wherein, in the second operation mode, the first multiplexer outputs the second input signal from the first storage element to the second transmission path, and the second multiplexer outputs the second input signal from the second transmission path to the second storage element.

5. The semiconductor integrated circuit according to claim 1, wherein the TEG circuit includes a TEG for evaluating a digital characteristic of the semiconductor integrated circuit.

6. The semiconductor integrated circuit according to claim 1, wherein the TEG circuit includes a TEG for evaluating an analog characteristic of the semiconductor integrated circuit.

7. The semiconductor integrated circuit according to claim 1,
wherein the TEG circuit includes a plurality of TEGs, and
wherein each of the plurality of TEGs includes vias differing in number or shape from the vias included in the other TEGs.

8. The semiconductor integrated circuit according to claim 1,
wherein the TEG circuit includes a plurality of TEGs, and
wherein each of the plurality of TEGs includes an interconnect differing in width from the interconnects included in the other TEGs.

9. The semiconductor integrated circuit according to claim 1, wherein the test circuit and the TEG circuit are formed on a semiconductor chip.

10. The semiconductor integrated circuit according to claim 1, further comprising a plurality of circuit blocks each including the test circuit, the TEG circuit, and the switching circuit.

11. The semiconductor integrated circuit according to claim 10, wherein the plurality of circuit blocks are connected in series.

12. The semiconductor integrated circuit according to claim 11, further comprising a third storage element configured to hold the first input signal or the second input signal output from a final-stage circuit block among the plurality of circuit blocks.

13. An equipment comprising:
a photoelectric conversion device including the semiconductor integrated circuit according to claim 1; and
at least one of
an optical device corresponding to the photoelectric conversion device,
a control device configured to control the photoelectric conversion device,
a processing device configured to process a signal output from the photoelectric conversion device,
a display device configured to display information obtained by the photoelectric conversion device,
a storage device configured to store information obtained by the photoelectric conversion device, and
a mechanical device configured to operate based on information obtained by the photoelectric conversion device.

14. The equipment according to claim 13, wherein the processing device obtains distance information from the photoelectric conversion device to an object.
